(19) United States
(12) Patent Application Publication
(10) Pub. No.: US 2022/0089930 A1
(43) Pub. Date: Mar. 24, 2022

(54) ANISOTROPIC HEAT-CONDUCTING RESIN MEMBER AND HEAT-TRANSMITTING SUBSTRATE

(71) Applicants: Showa Denko Materials Co., Ltd., Tokyo (JP); The University of Tokyo, Tokyo (JP)

(72) Inventors: Yoshitaka TAKEZAWA, Chiyoda-ku, Tokyo (JP); Masahiro NOMURA, Bunkyo-ku, Tokyo (JP)

(73) Assignees: Showa Denko Materials Co., Ltd., Tokyo (JP); The University of Tokyo, Tokyo (JP)

(21) Appl. No.: 17/422,440

(22) PCT Filed: Jan. 29, 2020
(86) PCT No.: PCT/JP2020/003265

§ 371 Date: Jul. 12, 2021

(30) Foreign Application Priority Data
Jan. 30, 2019 (JP) 2019-014390

(51) Int. Cl. C09K 5/14; H05K 7/20; D02J 1/22

(52) U.S. Cl. CPC C09K 5/14; D10B 2401/041; D02J 1/221; H05K 7/2039

(57) ABSTRACT

One aspect of the present invention is an anisotropic heat-conducting resin member provided with a first fiber group including multiple stretched thermoplastic resin fibers that have been bundled and a second fiber group and a third fiber group that the first fiber group branches to.

### TECHNICAL FIELD

The present invention relates to an anisotropic heat-conducting resin member and a heat-transmitting substrate.

### BACKGROUND ART

As electronic devices have electronic components that are more highly integrated, miniaturized, thinned, and the like in recent years, problems in reliability such as heat generated from and accumulated in the electronic components, malfunction of the electronic devices, and a reduced lifespan easily occur. Thus, emitting heat generated from electronic components to the outside through an appropriate path with efficiency is important.

To deal with such problems, a resin member with excellent heat conductivity and electrical insulation property is provided between an electronic component and a heat sink. As a sheet of that kind, for example, Patent Literature 1 discloses a heat conducting sheet that includes a heat-conducting filler, fibers, and a resin, in which the fibers are entangled in a plane shape, the entangled fibers carry the heat-conducting filler to form a base sheet, and the base sheet is filled with the resin.

### REFERENCE LIST

### Patent Literature

Patent Literature 1: Japanese Patent Application Laid-Open No. 2017-87446

### SUMMARY

### Technical Problem

However, because heat is conducted isotropically without directivity, when a heat-conducting sheet as described in Patent Literature 1 is used, heat is conducted not only in the direction in which the heat is supposed to be conducted (the direction from an electronic component to a heat sink) but also, for example, toward another electronic component in an electronic device. In this case, there is concern that an electronic component that is vulnerable to heat may be exposed to heat, which impairs reliability of the electronic device. However, because a resin is less likely to have a regular structure like a crystal structure, it is difficult to freely impart anisotropy (directivity) to heat conduction of a resin member.

Therefore, an objective of the present invention is to provide a resin member that can conduct heat anisotropically with efficiency and a heat-transmitting substrate using the resin member.

### Solution to Problem

An aspect of the present invention is an anisotropic heat-conducting resin member including a first fiber group with multiple stretched thermoplastic resin fibers that are bundled, and a second fiber group and a third fiber group that the first fiber group branches to.

Because the stretched fiber is a fiber with a high orientation property in the resin member, phonons that are heat carriers can be confined in the stretched fiber even though the fiber is formed of a thermoplastic resin having low crystallinity. Thus, the resin member conducts heat in the direction in which the stretched fiber extends with anisotropy (directivity). In addition, the resin member can conduct heat with efficiency because multiple stretched fibers are bundled, which increases an area of the heat conduction path (stretched fibers). Furthermore, since the bundled multiple stretched fibers are divided into at least branches of the two fiber groups in the resin member, heat conducted in one direction can branch in two or more directions, and heat conducted from two or more directions can be combined in one direction. Thus, with the resin member, a path on which heat is conducted (a heat transmission path) can be freely wired like electrical wiring (e.g., copper circuit wires).

Another aspect of the present invention is a heat-transmitting substrate including a substrate and an anisotropic heat-conducting resin member provided on the substrate.

The heat-transmitting substrate may further include a heat storage member that is thermally connected to the anisotropic heat-conducting resin member, a heat insulating member that is thermally connected to the anisotropic heat-conducting resin member, and a photothermal conversion member that is thermally connected to the anisotropic heat-conducting resin member.

### Advantageous Effects of Invention

According to the present invention, it is possible to provide a resin member that can conduct heat anisotropically with efficiency and a heat-transmitting substrate using the resin member.

### BRIEF DESCRIPTION OF THE DRAWINGS

(a) of FIG. 1 is a perspective diagram showing a resin member according to an embodiment, and (b) of FIG. 1 is a schematic diagram showing movement of a phonon in a stretched fiber.

FIG. 2 is a schematic diagram showing a stretched fiber production step according to an embodiment.

FIG. 3 is a schematic diagram showing a heat-transmitting substrate according to an embodiment.

FIG. 4 is a schematic diagram showing a heat-transmitting substrate according to another embodiment.

FIG. 5 is a schematic diagram for describing heat conduction in the heat-transmitting substrate.

FIG. 6 is a schematic diagram for describing a related art.

### DESCRIPTION OF THE EMBODIMENTS

Embodiments of the present invention will be described in detail below with reference to the drawings.

(a) of FIG. 1 is a perspective diagram showing a resin member according to an embodiment. As illustrated in (a) of FIG. 1, a resin member 1 has multiple stretched fibers (also referred to as fiber strands) 2 that are bundled. The resin member 1 has a first fiber group 1a with the multiple stretched fibers 2 that are bundled, and a second fiber group 1b and a third fiber group 1c that the first fiber group 1a branches to. In other words, the resin member 1 is a member formed in a fiber shape with a branch structure.

Each of the second fiber group 1b and the third fiber group 1c has multiple stretched fibers 2 that are bundled, like the first fiber group 1a. The multiple stretched fibers 2 included in the second fiber group 1b correspond to some of the multiple stretched fibers 2 included in the first fiber group 1a, and the multiple stretched fibers 2 included in the third fiber group 1c correspond to the rest of the multiple stretched fibers 2 included in the first fiber group 1a. A ratio between the number of stretched fibers 2 included in the second fiber group 1b and the number of stretched fibers 2 included in the third fiber group 1c may be arbitrary.

The multiple stretched fibers 2 are put together (bundled) using, for example, a bonding material 3 that bonds the stretched fibers 2 to help the fibers extend in the same direction. The multiple stretched fibers 2 may be arranged regularly or irregularly when viewed in a cross section. A cross-sectional shape of the stretched fibers 2 may be, for example, substantially a perfect circle as shown in (a) of FIG. 1, may be a fixed shape such as an oval or a polygon, or may be amorphous.

The stretched fibers 2 are fibers created by stretching a thermoplastic resin. The thermoplastic resin may be, for example, an acrylic polymer, a methacrylic polymer, a polyamide, polyethylene terephthalate, polyarylate, polysulfone, polyether etherketone, or the like.

A diameter of each stretched fiber 2 is preferably 0.1 μm or more, more preferably 10 μm or more, and even more preferably 100 μm or more in view of compatibility of easy confinement with easy incidence of phonons. A diameter of each stretched fiber 2 is preferably 1000 μm or less, more preferably 500 μm or less, and even more preferably 200 μm or less in view of the bundling property at the time of bundling the fibers.

The bonding material 3 is not particularly limited, and may be formed from, for example, a polyurethane, an acrylic polymer, an epoxy resin, or the like.

(b) of FIG. 1 is a schematic diagram showing movement of a phonon in a stretched fiber 2. Although the stretched fiber 2 is formed of a thermoplastic resin having low crystallinity because it is a fiber with a high orientation property, the phonon P is easily confined in the stretched fiber 2 as shown in (b) of FIG. 1. Thus, heat (phonon) is conducted with anisotropy (directivity) in the stretching direction of the stretched fiber 2. In other words, the resin member 1 is an anisotropic heat-conducting resin member with anisotropic heat conductivity that can conduct heat anisotropically in one direction of the stretching direction of the stretched fiber 2. In addition, because the multiple stretched fibers 2 are bundled in the resin member 1, which increases the cross-sectional area of the path for heat conduction (the stretched fibers), highly efficient heat conduction is possible.

Furthermore, because the bundled multiple stretched fibers 2 branch to the two fiber groups 1b and 1c in the resin member 1, when heat is incident from the first fiber group 1a, the heat conducted from the one direction can branch in two or more directions, however, when heat is incident from the second fiber group 1b and the third fiber group 1c, the heat conducted from two or more directions can be combined in one direction. Thus, a path on which heat is conducted (heat transmission path) can be freely arranged in the resin member 1, like electrical wiring (e.g., a copper circuit wire).

Next, a manufacturing method for the resin member 1 will be described. This manufacturing method includes a step of producing the stretched fibers by stretching a thermoplastic resin (a stretched fiber production step) and a step of bundling the multiple stretched fibers (a bundling step).

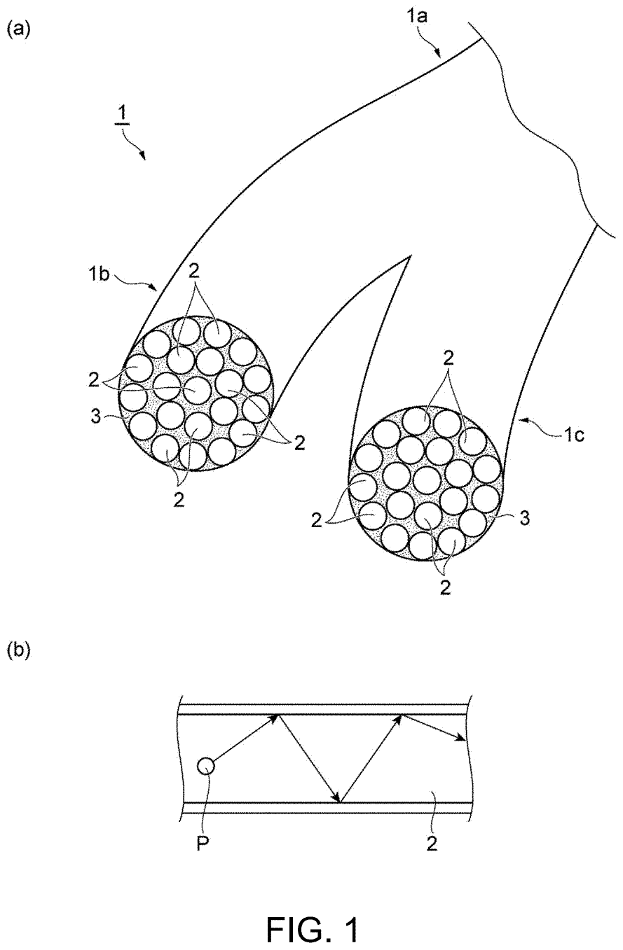

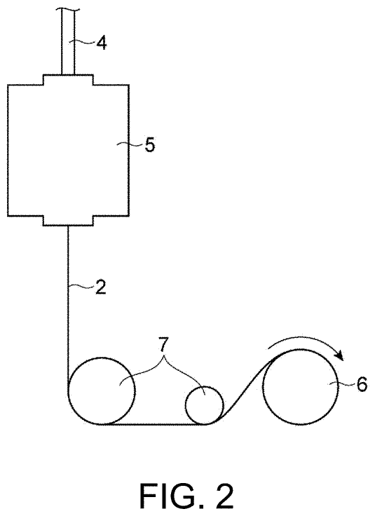

FIG. 2 is a schematic diagram showing the stretched fiber production step according to an embodiment. In the stretched fiber production step, first, a thermoplastic resin 4 is heated in a heating furnace 5 and wound (pulled) by a winding part 6 in a winding direction (pulling direction) to be stretched. Specifically, first, the thermoplastic resin 4, for example, molded in a rod shape having a diameter of 5 to 50 mm is input to the heating furnace 5. The thermoplastic resin 4 is heated in the heating furnace 5 and wound (pulled) by the winding part 6 installed next to the heating furnace 5 to be stretched.

A temperature of the heating furnace 5 is appropriately set according to a softening temperature of the thermoplastic resin 4, and preferably is a temperature equal to or higher than a thermal deformation temperature of the thermoplastic resin and lower than a melting point in view of favorably imparting an orientation property when the thermoplastic resin 4 is stretched. The thermoplastic resin 4 is stretched under the condition of, for example, a stretching ratio of 10 to 1000.

The stretched fiber 2 coming out of the heating furnace 5 as described above is formed in a thin line shape having a smaller diameter than the thermoplastic resin 4 (the diameter of the rod) before being input to the heating furnace 5. The stretched fiber 2 is wound by the winding part 6 along a roll 7 appropriately installed between the heating furnace 5 and the winding part 6.

In the bundling step following the stretched fiber production step, multiple stretched fibers 2 are prepared, and these multiple stretched fibers 2 are put together to be bundled using, for example, the bonding material 3. A bundling method may be a known method. In addition, when one fiber group (the first fiber group 1a) including the bundled multiple stretched fibers 2 branches to two fiber groups (the second fiber group 1b and the third fiber group 1c), the resin member 1 is obtained.

Although the resin member 1 has the form in which the first fiber group 1a branches to the second fiber group 1b and the third fiber group 1c in the above-described embodiment, the resin member may have a form in which one or both of the second fiber group 1b and the third fiber group 1c further branch to two or more fiber groups in another embodiment. Although the first fiber group 1a branches to the two group fibers including the second fiber group 1b and the third fiber group 1c in the above-described embodiment, the first fiber group 1a may branch to three or more fiber groups in another embodiment.

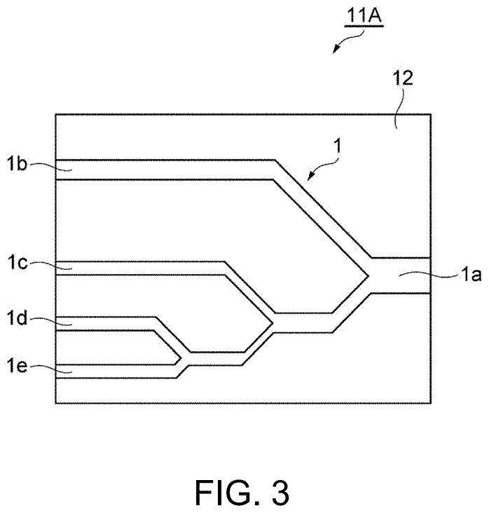

FIG. 3 is a schematic diagram showing a heat-transmitting substrate (which may also be referred to as a thermal circuit) according to an embodiment. The heat-transmitting substrate 11A includes a substrate 12 and a resin member 1 provided on the substrate 12 according to an embodiment as shown in FIG. 3. Grooves (not illustrated) corresponding to positions at which the resin member 1 is disposed are provided on the substrate 12 to allow the resin member 1 to be disposed in the grooves.

The substrate 12 may be formed of, for example, a known material (a resin, etc.). A planar shape of the substrate 12 may be, for example, a rectangle with a side of 1 to 50 cm. A thickness of the substrate 12 may be, for example, 1 to 10 mm.

The resin member 1 has a shape in which one fiber group branches to multiple fiber groups. In this embodiment, the resin member 1 has a shape in which a first fiber group branches to a second fiber group and a third fiber group, the third fiber group further branches to a fourth fiber group and a fifth fiber group, and the fifth fiber group further branches to a sixth fiber group and a seventh fiber group. In other words, in the resin member 1, the first fiber group 1a ultimately branches to four fiber groups including the second fiber group 1b, the fourth fiber group 1c, the sixth fiber group 1d, and the seventh fiber group 1e.

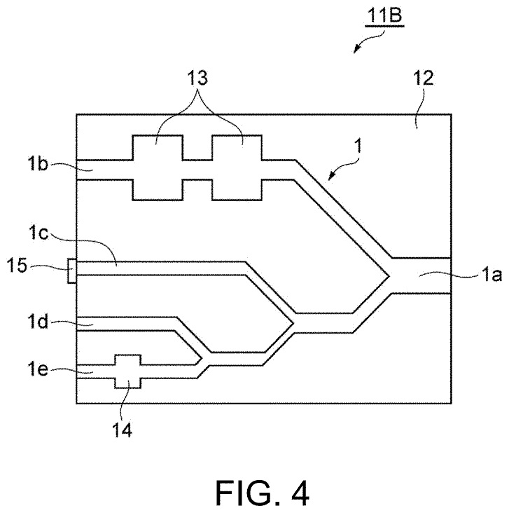

FIG. 4 is a schematic diagram showing a heat-transmitting substrate according to another embodiment. As illustrated in FIG. 4, the heat-transmitting substrate 11B according to the other embodiment includes a substrate 12, a resin member 1 provided on the substrate 12, heat storage members 13 that are thermally connected to a second fiber group 1b of the resin member 1, a heat insulating member 14 that is thermally connected to a seventh fiber group 1e of the resin member 1, and a photothermal conversion member (also referred to as a thermal radiation-light conversion member) 15 that is thermally connected to a fourth fiber group 1c of the resin member 1.

The heat storage members 13 are members that can store heat and may be composed of, for example, paraffin. The heat insulating member 14 is a member that can insulate heat and may be composed of, for example, a vacuum heat insulating material. The photothermal conversion member 15 is a member that can convert heat energy to light energy and may be composed of, for example, a metamaterial.

Although the one heat-transmitting substrate 11B includes the heat storage members 13, the heat insulating member 14, and the photothermal conversion member 15 in this embodiment, one heat-transmitting substrate may include only one type or two types of components selected from a heat storage member, a heat insulating member, and a photothermal conversion member in another embodiment.

In the above-described heat-transmitting substrates 11A and 11B, a path on which heat is conducted (a heat transmission path) can be freely arranged like electrical wiring (e.g., a copper circuit wire) by using the resin member 1. In other words, because the resin member 1 that enables anisotropic heat conduction is used in the above-described heat-transmitting substrates 11A and 11B, a direction in which heat is conducted (transmitted) can be freely controlled. This point will be described in more detail exemplifying the heat-transmitting substrate 11B of FIG. 4.

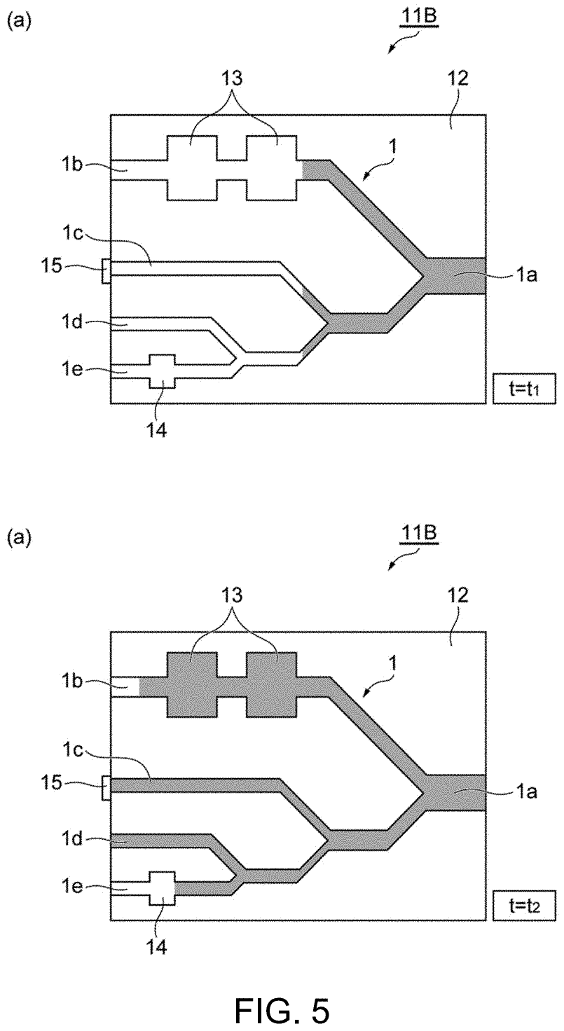

FIG. 5 is a schematic diagram for describing heat conduction of the heat-transmitting substrate. Heat incident from the first fiber group 1a is conducted by the resin member 1 (stretched fibers 2) in the direction in which the resin member 1 stretches at, for example, a predetermined time t=t₁, as shown by the shaded portion in (a) of FIG. 5. Successively, at a predetermined time t=t₂ (t₂>t₁), the heat is further conducted by the resin member 1 (stretched fibers 2) in the direction in which the resin member 1 extends, as shown by the shaded portion in (b) of FIG. 5. At this time, heat transmission stagnates on the path on which the heat storage members 13 are provided until an amount of heat stored in the heat storage members 13 is saturated, and thus a heat transmission rate on the entire path is lower than a heat transmission rate on the path on which no heat storage members are provided. The heat transmission stops before the heat insulating member 14 on the path on which the heat insulating member 14 is provided. The conducted heat energy is converted to light energy on the path on which the photothermal conversion member 15 is provided.

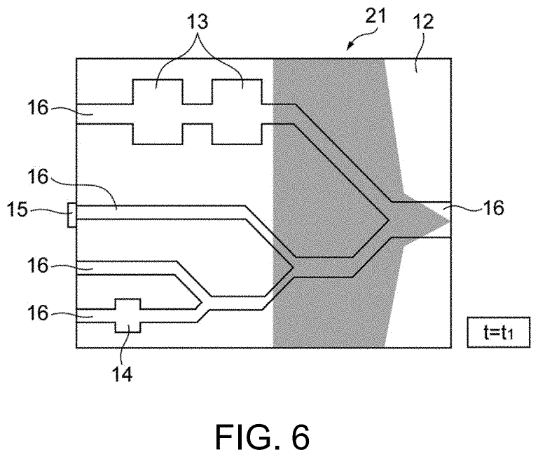

Meanwhile, when a conventional member made of a resin (a conventional member) is used instead of the above-described resin member 1, a direction in which heat is conducted cannot be freely controlled, unlike the case described above. FIG. 6 is a schematic diagram for describing a conventional technique. In a conventional substrate 21 using a conventional member 16 instead of the resin member 1, the conventional member 16 cannot conduct heat anisotropically (conducts heat isotropically) as shown in FIG. 6, and thus heat is conducted not only by the conventional member 16 but also by the substrate 12 isotropically at, for example, a predetermined time t=t₁, as indicated by the shaded portion in FIG. 6. Therefore, in the conventional substrate 21 using the conventional member 16 instead of the resin member 1, a direction in which heat is conducted cannot be freely controlled.

### REFERENCE SIGNS LIST

1 Resin member

1a, 1b, 1c, 1d, and 1e Fiber group

2 Stretched fiber

3 Bonding material

4 Thermoplastic resin

5 Heating furnace

6 Winding part

7 Roll

11A, 11B Heat-transmitting substrate

12 Substrate

13 Heat storage member

14 Heat insulating member

15 Photothermal conversion member

16 Conventional member

21 Conventional substrate

1. An anisotropic heat-conducting resin member comprising a first fiber group with multiple stretched thermoplastic resin fibers that are bundled, and a second fiber group and a third fiber group that the first fiber group branches to.

2. A heat-transmitting substrate comprising a substrate and the anisotropic heat-conducting resin member according to claim 1 provided on the substrate.

3. The heat-transmitting substrate according to claim 2, further comprising a heat storage member that is thermally connected to the anisotropic heat-conducting resin member.

4. The heat-transmitting substrate according to claim 2, further comprising a heat insulating member that is thermally connected to the anisotropic heat-conducting resin member.

5. The heat-transmitting substrate according to claim 2, further comprising a photothermal conversion member that is thermally connected to the anisotropic heat-conducting resin member.

6. The heat-transmitting substrate according to claim 3, further comprising a heat insulating member that is thermally connected to the anisotropic heat-conducting resin member.

7. The heat-transmitting substrate according to claim 3, further comprising a photothermal conversion member that is thermally connected to the anisotropic heat-conducting resin member.

8. The heat-transmitting substrate according to claim 4, further comprising a photothermal conversion member that is thermally connected to the anisotropic heat-conducting resin member.

9. The heat-transmitting substrate according to claim 6, further comprising a photothermal conversion member that is thermally connected to the anisotropic heat-conducting resin member.
